(19) United States
(12) Patent Application Publication
(10) Pub. No.: US 2016/0183411 A1
(43) Pub. Date: Jun. 23, 2016

(54) COOLING BODY

(71) Applicant: ROBERT BOSCH GMBH, Stuttgart (DE)

(72) Inventors: Paul Butsch, Buehlertal (DE); Christian Meyer, Karlsruhe-Wolfartsweìer (DE)

(21) Appl. No.: 14/907,406

(22) PCT Filed: Jul. 3, 2014
(86) PCT No.: PCT/EP2014/064238

§ 371 Date: Jan. 25, 2016

(30) Foreign Application Priority Data
Jul. 25, 2013 (DE) 10 2013 214 516.0

(51) Int. Cl. H05K 7/20; B23P 15/26

(52) U.S. Cl. CPC H05K 7/20418; B23P 15/26; B23P 2700/10

(57) ABSTRACT

The invention relates to a method for producing a cooling body made of a good heat-conducting metal material, comprising the following steps; placing the metallic material (310) between a first die (315) and a second die (320), the dies are pressed against each other such that the metallic material adapts to the shape of the dies, the dies are separated from each other and the cooling body (100) is demoulded from the dies.

### BACKGROUND OF THE INVENTION

The invention relates to a cooling body and a method for producing the cooling body. The invention particularly relates to a cooling body on an electrohydraulic unit.

### TECHNICAL FIELD

A cooling body has the task of absorbing heat from an element to be cooled and releasing said heat to an ambient medium. As a result, a material having a high level of thermal conductivity, such as aluminum or copper, is generally used for the cooling body.

A mass production of aluminum cooling bodies, in particular those in the form of which are adapted to a predetermined application, usually involves a die casting process. In such a process, heated aluminum in the liquid or pasty state is pressed under pressure into a preheated steel mold. After the aluminum has cooled, the cooling body can be removed from the mold. In so doing, the mold is exposed to considerable thermal stress so that said mold has to be replaced after a number of cooling bodies have been produced. The die casting process furthermore requires an extensive process control. In addition, the high-pressure die casting of aluminum is limited to the cold-chamber die casting process. Moreover, only certain alloys of aluminum are suited to aluminum high-pressure die casting and it can be difficult to produce the steel mold such that the workpiece has the appropriate degree of shrinkage after cooling.

For certain applications, it is necessary to produce a specially molded cooling body. In order to cool an electrohydraulic actuator, for example to actuate a brake or a clutch, a cooling body can, for example, be required which can transport a considerable amount of waste heat, which accrues, for example, at electronic power components of an engine control system. If the electrohydraulic actuator is used in a safety related system, for example the braking system of a vehicle, the cooling body must also be designed such that the efficiency of the actuator is also ensured under unfavorable conditions. In addition, the cooling body at the actuator can also be used as a structural component which ensures a mechanical protection of the aforementioned electronic components. The cooling body can particularly be configured in the form of a housing cover, which, for example, is disposed in the axial extension of an electric motor.

### SUMMARY OF THE INVENTION

The aim of the present invention consists of specifying a cooling body and a method of production for the cooling body which are adapted to the needs of an electrohydraulic actuator, in particular on board of a motor vehicle.

A cooling body according to the invention comprises a lower section having a contact surface for absorbing heat from an element to be cooled and an upper section comprising an upwardly extending projection for transferring heat to an ambient medium, wherein the cooling body is produced from a good heat-conducting metal material by means of impact extrusion.

During impact extrusion of a component, in contrast to a die casting process, the metal material is brought to flow into a die by means of high pressure rather than heat. In so doing, the material begins, in a metallurgical sense, to flow without being heated into the range of the melting temperature thereof. As a result, the impact extrusion can also be carried out at room temperature. The temperatures reached during such a process fatigue the tool, particularly the die, to a lesser extent; thus enabling the die to be used over a longer production period or, respectively, for an increased number of pieces. The metal material can particularly comprise a good ferrous material or a non-ferrous material, wherein a good conductivity of the material is advantageous. In a preferred manner, the metal material comprises aluminum as a non-ferrous metal.

Because a cooling process is not required for the workpiece, a higher rate of production can be achieved with the impact extrusion process than with, for example, high-pressure die casting. Impact extrusion can furthermore ensure a high degree of dimensional accuracy of the cooling body. A surface quality of the impact extruded cooling body can be so high that a post-processing of the workpiece can be omitted. In addition, the impact extrusion process tends only slightly to form ridges and cavities (cast hollow spaces).

The contact surface of the cooling body preferably bears a profile. The profile can be provided during the same operation as for the rest of the cooling body and can facilitate the use of a thermal paste or a thermal pad. Heat of an object to be cooled, in particular an electronic component, can thus be better released to the cooling body.

The projection can have the shape of a conical section. As a result, a relatively large surface can be combined with a good stability of the projection.

In another embodiment of the invention, the projection has the shape of a cylinder. The durability of the projection can be further increased by means of the cylindrical shape. In still a further embodiment of the invention, the projection can also be cuboid-shaped, wherein one of the dimensions of the cuboid is preferably small with respect to the other dimensions.

The cuboid-shaped projection can particularly form a large surface area at a low volume.

In a preferable manner, a plurality of projections is provided, wherein projections having different shapes can be combined with one another.

In one embodiment of the invention, the cooling body has a substantially circular base area. As a result, the cooling body is particularly suitable for installation in the axial extension of a cylindrical electric motor.

A cuboid-shaped projection can particularly extend in the radial direction. A plurality of cuboid-shaped, radial projections can be formed as a type of annulus around the geometric center of the cooling body.

In a further preferred embodiment of the invention, the lower section of the cooling body has a planar sealing surface for engagement with a seal. As a result, the cooling body can, for example, be used as an axial closure of a housing. On account of the impact extrusion process, the sealing surface can have a high quality without a post-processing step.

In one embodiment of the invention, a retaining element is provided on the upper section for engaging a hook element which is designed to press the cooling body downwards. By means of the hook element, the cooling body can be provided for a screwless mounting, for example, on the aforementioned electrohydraulic actuator. A post-processing step for the impact extruded cooling body, for example for inserting a screw thread, can be omitted. The cooling body can therefore be configured for a cost effective and simple installation.

A method according to the invention for producing a cooling body, in particular the cooling body mentioned above, made of a good heat-conducting metal material comprises the following steps: placing the metallic material between a first die and a second die, pressing the dies against each other such that the metallic material adapts to the shape of the dies, separating the dies from each other and demolding the cooling body from the dies. The metal material preferably comprises aluminum.

By producing the cooling body in an impact extrusion process, the features of the cooling body mentioned above can be advantageously formed. The method allows for a cost effective production of the cooling body, in particular in large quantities.

### BRIEF DESCRIPTION OF THE DRAWINGS

The invention is now described in greater detail with reference to the attached drawings. In the drawings:

FIG. 1 shows a cooling body for an electrohydraulic unit;

FIG. 2 shows the cooling body from FIG. 1 from a different perspective, and

FIG. 3 shows a flow diagram of a method for producing the cooling body of the FIGS. 1 and 2.

### DETAILED DESCRIPTION

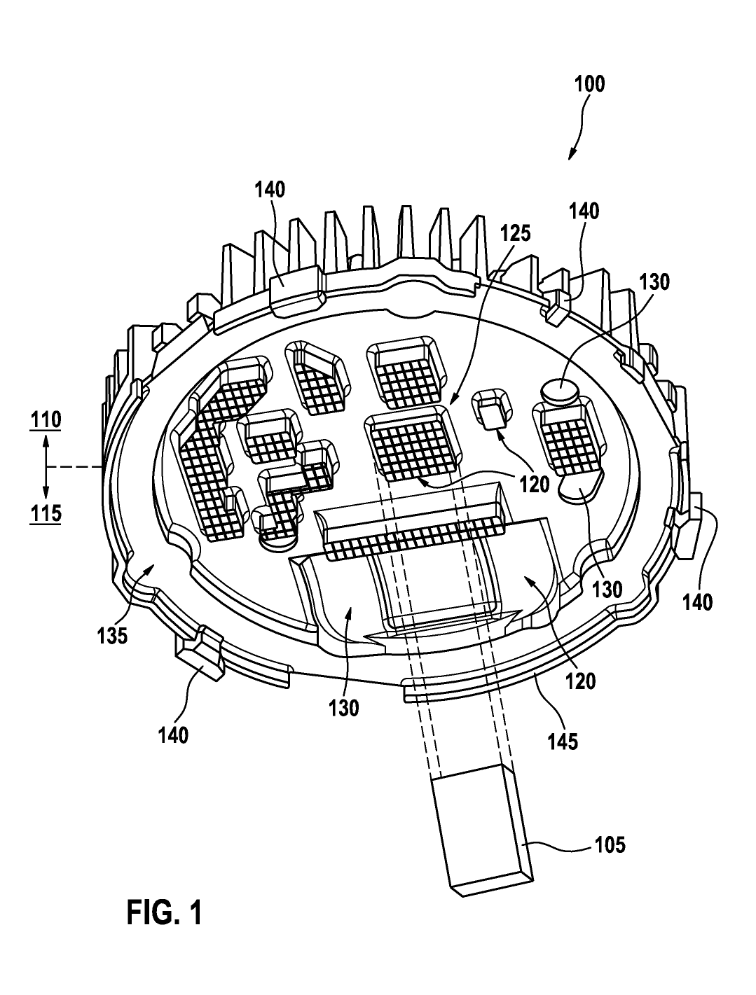

FIG. 1 shows a cooling body 100 for an electrohydraulic unit. The cooling body 100 is particularly designed to axially close off an electric motor of the electrohydraulic unit. An element to be cooled by the cooling body 100 can, for example, be an electronic component which is axially disposed between the cooling body 100 and the electric motor. The cooling body 100 has, in the depiction of FIG. 1, a substantially circular base area, from which an upper section 110 and a lower section 115 extend in the axial direction. One or a plurality of contact surfaces 120 is configured on the lower section 115 for engaging the element 105. At least one of the contact surfaces 120 preferably bears a profile 125. The profile 125 can, for example, comprise one or a plurality of grooves which are introduced axially into the lower section 115 in the region of the contact surfaces 120 in a grid- or diamond-shaped manner. The lower section 115 can also have a recess 130 which is introduced in the axial direction of the upper section 110. By means of the recess 130, space can be made available for an element lying in the proximity of the cooling body 100, in particular an electrohydraulic actuator. The recess 130 can also be entirely or partially delimited by a contact surface 120, against which an element to be cooled 105 can rest. One or a plurality of other contact surfaces 120 can be disposed away from the upper section 110 in the axial direction.

In one embodiment of the invention, a planar sealing surface 135 is provided on the lower section 115, which is provided for engagement with a seal, for example made from rubber, plastic or paper. The sealing surface 135 preferably encompasses an area of the lower section 115 or, respectively, the base area of the cooling body 100. In the embodiment depicted, in which the cooling body 100 has a substantially circular base area, it is preferred that the sealing surface 135 runs in a radially outer region.

The lower section 115 can bear one or a plurality of extensions 140 which extend away from the upper section 110 in the axial direction. The extensions 140 can keep the cooling body 100 from twisting by virtue of the fact that they are designed to engage in corresponding grooves of a component, to which the cooling body 100 is to be attached. In a preferred manner, the cooling body 100 can, for example, be mounted in only one rotatory position, for example on a housing. A web 145 can be provided in one exemplary embodiment, which passes around the outside of the base area at least in some sections. In so doing, the cooling body 100 can be placed in a cup-like manner over a proximate element and be mounted to the same.

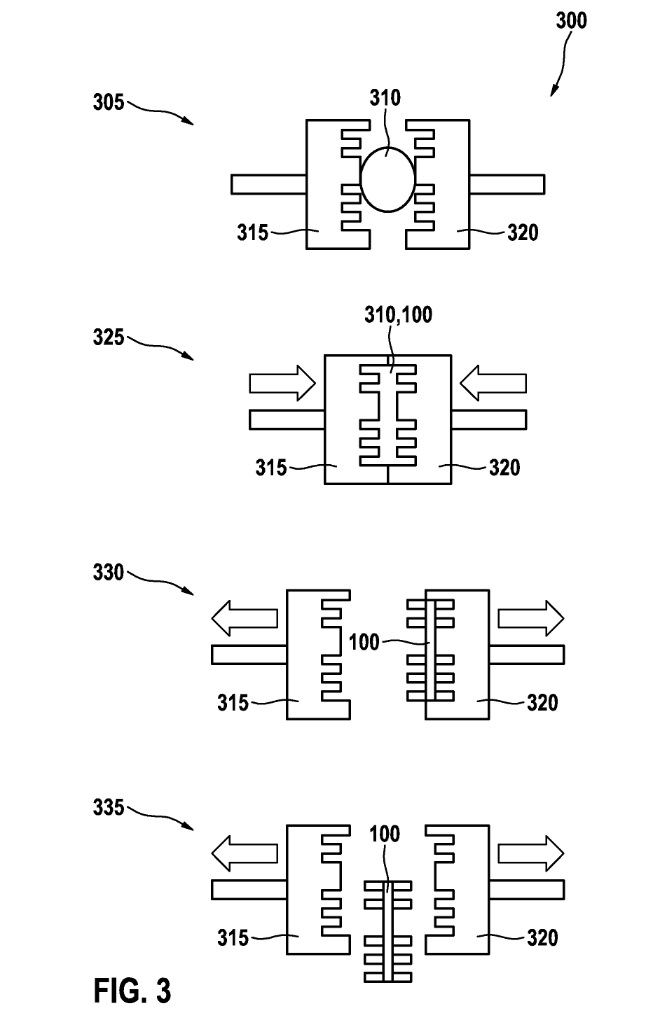

The cooling body 100 is designed to be demolded from the dies in the axial direction, as is described below in greater detail with reference to FIG. 3. To this end, it is preferred that the cooling body 100 does not have any undercuts. It is furthermore preferred that delimiting structures of the cooling body 100 do not extend exactly in the axial direction but rather slightly obliquely thereto to the greatest possible extent.

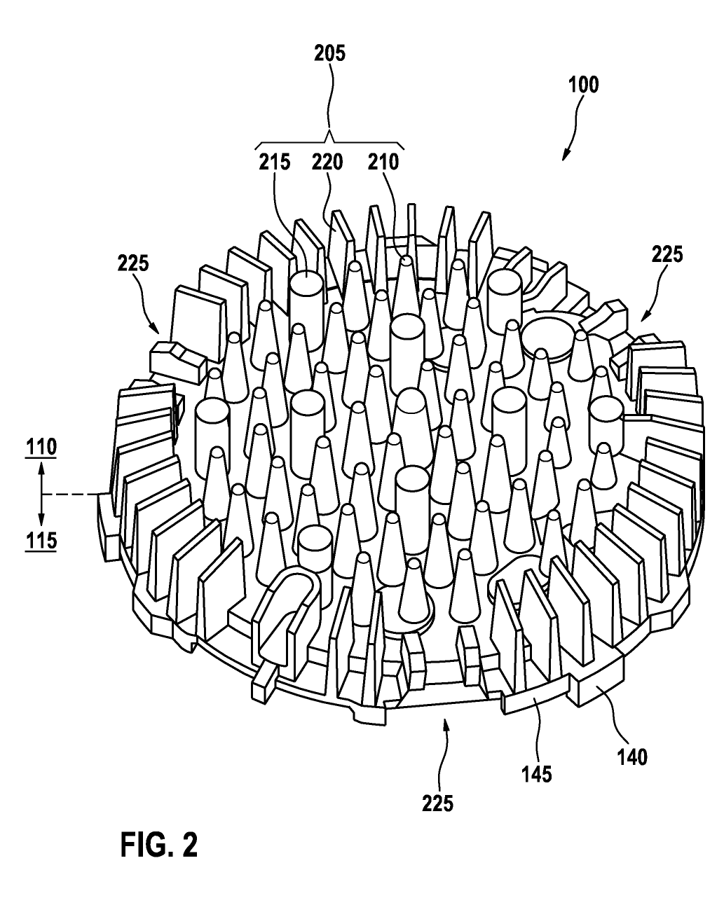

FIG. 2 shows the cooling body 100 from FIG. 1 in a view from the upper section 110. One or a plurality of projections 205 extend axially in a direction away from the lower section 115. The projection 205 can assume different forms. In a preferred embodiment, a multiplicity of projections 205 is provided which can have the same or different shapes. A first projection 210 can, for example, have the shape of a conical section. A cone that is rounded off at the top or, respectively, a frustum comprising a convex top surface is preferred in this case. A second projection 215 has the shape of a cylinder. A third projection 220 is cuboid-shaped. A multiplicity of third projections 220 is disposed on a periphery about a geometric center of the circular base area of the cooling body 100, wherein the cuboids are oriented in a radial direction. An annulus of third projections 220 is thereby formed in a radial outer region of the cooling body 100. A retaining element 225 for engaging a hook element is preferably provided, which is designed to press the cooling body 100 downwards, i.e. in the direction of the lower section 115. The hook element can, for example, comprise a spring clip, a hook plate or a spring wire.

The upper section 110 is also designed to be demolded from a die. For that reason, delimiting structures that extend axially are also preferably omitted here if possible.

FIG. 3 shows a flow diagram of a method for producing a cooling body, in particular those of FIGS. 1 and 2.

In a first step 305, a metallic material 310 is placed between a first die 315 and a second die 320. The aluminum material 310 can comprise pure aluminum or a suitable alloy. The aluminum can, for example, be alloyed with silicon, copper, manganese or iron. The dies 315 and 320 are preferably made from steel. The first die 315 has a mold which corresponds to the negative mold of the upper section 110, and the mold of the second die 320 corresponds to the negative mold of the lower section 115.

In a following step 325, the dies 315 and 320 are pressed under high pressure against one another. The pressure exerted by the dies 315 and 320 on the metallic material 310 is so great that the metallic material 310 begins to flow in a metallurgical sense without being heated into the range of the melting temperature thereof. This process is also known as cold extrusion. In said process, the metallic material 310 adapts to the shape of the dies 315 respectively 320 so that the cooling body 100 is formed.

In a following step 330, the dies 315 and 320 are separated from each other, wherein the cooling body 100 is usually demolded from at least one of the dies 315, 320.

In a concluding step 335, the cooling body 100 is completely demolded so that said body is free from both dies 315, 320. A cooling process of the cooling body 100 is usually not required and said cooling body 100 can immediately be further processed. A surface processing of the cooling body 100 is usually no longer required because the extrusion process can ensure a high degree of dimensional accuracy and high quality surfaces. The dies 315 and 320 are immediately ready for the method to be rerun with a new metallic material 310.

1. A cooling body (100) comprising:
a lower section comprising a contact surface (120) for absorbing heat from an element to be cooled, and
an upper section (110) comprising a projection (205) that extends upwards for transferring heat to an ambient medium,
wherein the cooling body (100) is made of a good heat-conducting metal material (310),
characterized in that
the cooling body (100) is produced by means of an impact extrusion method.

2. The cooling body (100) according to claim 1, wherein the contact surface (120) bears a profile.

3. The cooling body (100) according to claim 1, wherein the projection (205) has the shape of a conical section (210).

4. The cooling body (100) according to claim 1, wherein the projection (205) has the shape of a cylinder (215).

5. The cooling body (100) according to claim 1, wherein the projection (205) is cuboid-shaped.

6. The cooling body (100) according to claim 1, wherein the cooling body (100) has a substantially circular base area.

7. The cooling body (100) according to claim 5, wherein the projection (215) extends in a radial direction.

8. The cooling body (100) according to claim 1, wherein the lower section (115) has a planar sealing surface (135) for engagement with a seal.

9. The cooling body (100) according to claim 1, wherein a retaining element (225) for engaging a hook element is provided on the upper section (110) in order to press the cooling body (100) downwards.

10. A method (300) for producing a cooling body (100) made of a metal material (310), wherein the method (300) comprises the following steps:
placing (305) the metal material (310) between a first die (315) and a second die (320);
pressing (325) the dies (315, 320) against each other such that the metal material (310) adapts to the shape of the dies (315, 320);
separating (330) the dies (315, 320) from each other; and
demolding (335) the cooling body (100) from the dies (315, 320).

11. A method for producing a cooling body (100) including a lower section comprising a contact surface (120) for absorbing heat from an element to be cooled, and an upper section (110) comprising a projection (205) that extends upwards for transferring heat to an ambient medium, the method comprising:
providing a good heat-conducting metal material (310); and
using the material in an impact extrusion process to produce the cooling body.
